(19) United States
(12) Patent Application Publication
(10) Pub. No.: US 2024/0170622 A1
(43) Pub. Date: May 23, 2024

(54) SEMICONDUCTOR LIGHT EMITTING DEVICE AND METHOD OF MANUFACTURING THE SAME

(71) Applicant: ROHM CO., LTD., Kyoto (JP)

(72) Inventor: Kazuya MASUYAMA, Kyoto (JP)

(21) Appl. No.: 18/506,359

(22) Filed: Nov. 10, 2023

(30) Foreign Application Priority Data
Nov. 21, 2022 (JP) 2022-185601

(51) Int. Cl. H01L 33/56; H01L 33/00; H01L 33/48; H01L 33/50; H01L 33/60

(52) U.S. Cl. CPC H01L 33/56; H01L 33/0062; H01L 33/483; H01L 33/50; H01L 33/60

(57) ABSTRACT

A semiconductor light emitting device includes: a semiconductor light emitting element; a sealing member that seals the semiconductor light emitting element; and an overcoat layer that covers the sealing member, wherein the sealing member includes a sealing resin and has a first upper surface on an opposite side to the semiconductor light emitting element, and wherein the overcoat layer is formed of an inorganic material and is in direct contact with the first upper surface of the sealing member.

### CROSS-REFERENCE TO RELATED APPLICATION

This application is based upon and claims the benefit of priority from Japanese Patent Application No. 2022-185601, filed on Nov. 21, 2022, the entire contents of which are incorporated herein by reference.

### TECHNICAL FIELD

The present disclosure relates to a semiconductor light emitting device and a method of manufacturing the same.

### BACKGROUND

Japanese Patent Application Publication No. 2022-13369 (Patent Document 1) discloses a semiconductor light emitting device including a substrate, a semiconductor light emitting element, a reflective case, and a sealing resin.

### BRIEF DESCRIPTION OF DRAWINGS

The accompanying drawings, which are incorporated in and constitute a part of the specification, illustrate embodiments of the present disclosure.

FIG. 1 is a schematic cross-sectional view of a semiconductor light emitting device according to an embodiment.

FIG. 2 is a schematic cross-sectional view showing one step of a method of manufacturing a semiconductor light emitting device according to the embodiment.

FIG. 3 is a schematic cross-sectional view showing a next step after the step shown in FIG. 2 in the method of manufacturing a semiconductor light emitting device according to the embodiment.

FIG. 4 is a schematic cross-sectional view showing a next step after the step shown in FIG. 3 in the method of manufacturing a semiconductor light emitting device according to the embodiment.

FIG. 5 is a schematic cross-sectional view showing a next step after the step shown in FIG. 4 in the method of manufacturing a semiconductor light emitting device according to the embodiment.

FIG. 6 is a schematic cross-sectional view showing a next step after the step shown in FIG. 5 in the method of manufacturing a semiconductor light emitting device according to the embodiment.

FIG. 7 is a schematic cross-sectional view showing the semiconductor light emitting device of the embodiment, which is accommodated in a package.

FIG. 8 is a schematic cross-sectional view showing a step of taking out the semiconductor light emitting device of the embodiment from the package.

FIG. 9 is a schematic cross-sectional view showing a step of taking out a semiconductor light emitting device of a comparative example from a package.

FIG. 10 is a schematic cross-sectional view showing one step of a method of manufacturing a semiconductor light emitting device according to the comparative example.

FIG. 11 is a schematic cross-sectional view of a semiconductor light emitting device according to a first modification of the embodiment.

FIG. 12 is a schematic cross-sectional view of a semiconductor light emitting device according to a second modification of the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Details of embodiments of the present disclosure will be described with reference to the drawings. Throughout the drawings, the same or corresponding parts are denoted by the same reference numerals, and the explanation thereof will not be repeated. At least some of the configurations of the embodiments described below may be combined arbitrarily.

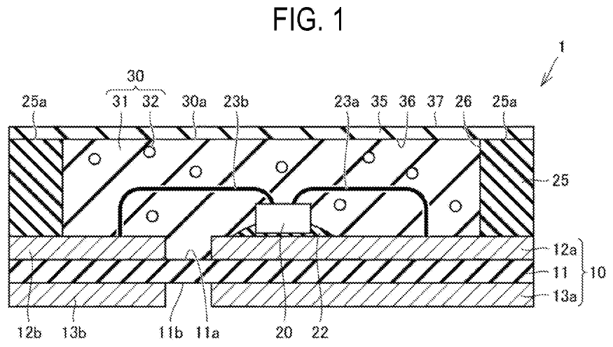

A semiconductor light emitting device 1 according to an embodiment will be described with reference to FIG. 1. The semiconductor light emitting device 1 mainly includes a substrate 10, a reflective case 25, a semiconductor light emitting element 20, conductive wires 23a and 23b, a sealing member 30, and an overcoat layer 35.

The substrate 10 supports the semiconductor light emitting element 20. The substrate 10 includes, for example, an insulating substrate 11, front conductive layers 12a and 12b, and back conductive layers 13a and 13b.

The insulating substrate 11 has a front surface 11a and a back surface 11b opposite to the front surface 11a. The insulating substrate 11 is, for example, a glass epoxy substrate formed of glass cloth and resin impregnated into the glass cloth.

The front conductive layers 12a and 12b are provided on the front surface 11a. The front conductive layers 12a and 12b are spaced apart from each other. The back surface conductive layers 13a and 13b are provided on the back surface 11b. The back conductive layers 13a and 13b are spaced apart from each other. The front conductive layers 12a and 12b and the back conductive layers 13a and 13b are formed of a conductive material such as copper. The front conductive layers 12a and 12b and the back conductive layers 13a and 13b may be covered with a plating layer (not shown) such as a gold plating layer or a silver plating layer.

The front conductive layer 12a and the back conductive layer 13a are electrically connected to each other via a through-via (not shown). The front conductive layer 12b and the back conductive layer 13b are electrically connected to each other via a through-via (not shown). The through-vias are formed of a conductive material such as copper. The substrate 10 is mounted on a wiring board (not shown). The wiring board includes wirings (not shown). The back conductive layers 13a and 13b are bonded to the wirings of the wiring board using a conductive bonding member (not shown) such as solder.

The reflective case 25 is arranged on the substrate 10. The reflective case 25 is attached to the front conductive layers 12a and 12b using an adhesive (not shown). The reflective case 25 has a top surface 25a on the opposite side to the substrate 10 and the semiconductor light emitting element 20. The reflective case 25 includes an accommodation part 26 in which the semiconductor light emitting element 20 is accommodated. The accommodation part 26 is recessed from the top surface 25a of the reflective case. The reflective case 25 is arranged around the semiconductor light emitting element 20 and surrounds the semiconductor light emitting element 20. The reflective case 25 reflects first light emitted from the semiconductor light emitting element 20 and second light emitted from a wavelength conversion member 32, which will be described later. The reflective case 25 is formed of synthetic resin to which a white filler such as a titanium oxide filler is added. This synthetic resin is, for example, polyethylene (PE), polypropylene (PP), vinyl chloride resin (PVC), polystyrene (PS), epoxy resin (EP), polyphthalamide (PPA), liquid crystal polymer (LCP), or the like.

The semiconductor light emitting element 20 is bonded to the substrate 10. The semiconductor light emitting element 20 is bonded to the front conductive layer 12a using a bonding member 22 such as epoxy resin paste. The semiconductor light emitting element 20 is arranged within the accommodation part 26 of the reflective case 25. The semiconductor light emitting element 20 is, for example, a light emitting diode (LED). The semiconductor light emitting element 20 is mainly formed of a semiconductor material such as gallium nitride (GaN). The semiconductor light emitting element 20 includes, for example, an n-type electrode (not shown) and a p-type electrode (not shown). The semiconductor light emitting element 20 emits the first light such as ultraviolet light or blue light.

The conductive wires 23a and 23b are connected to the semiconductor light emitting element 20. Specifically, the conductive wire 23a is connected to the semiconductor light emitting element 20 (for example, the n-type electrode) and the front conductive layer 12a. The conductive wire 23b is connected to the semiconductor light emitting element 20 (for example, the p-type electrode) and the front conductive layer 12b. The conductive wires 23a and 23b are formed of a conductive material such as gold, copper, or aluminum.

The sealing member 30 seals the semiconductor light emitting element 20. The sealing member 30 includes a sealing resin 31 and a wavelength conversion member 32.

The sealing resin 31 is a resin that is transparent to the first light emitted from the semiconductor light emitting element 20 and the second light emitted from the wavelength conversion member 32. The sealing resin 31 is formed of, for example, silicone resin. The sealing member 30 has an upper surface 30a on the opposite side from the semiconductor light emitting element 20.

The wavelength conversion member 32 is added to the sealing resin 31 and is dispersed in the sealing resin 31. The wavelength conversion member 32 converts the first light emitted from the semiconductor light emitting element 20 into the second light having a wavelength different from that of the first light, and emits the second light. For example, the second light has a longer wavelength than the first light. The wavelength conversion member 32 is, for example, one or more types of phosphor particles. The second light is, for example, fluorescent light. For example, when the first light is blue light, the wavelength conversion member 32 is a yellow fluorescent light formed of (Y, Gd)₃(Al, Ga)₅O₁₂: Ce³⁺ or (Ba, Sr, Ca)₂SiO₄: Eu²⁺, etc., and the second light is yellow light. The blue light and the yellow light mix to produce white light. The white light is emitted from the semiconductor light emitting device 1.

The wavelength conversion member 32 is not provided in the overcoat layer 35. The wavelength conversion member 32 is provided only in the sealing member 30 out of the sealing member 30 and the overcoat layer 35.

The overcoat layer 35 covers the sealing member 30. The overcoat layer 35 covers the entire upper surface 30a of the sealing member 30. The overcoat layer 35 is formed of an inorganic material. The inorganic material is, for example, SiO₂. The overcoat layer 35 has a lower surface 36 facing the semiconductor light emitting element 20, the substrate 10, the sealing member 30, and the reflective case 25, and an upper surface 37 opposite to the lower surface 36. The lower surface 36 of the overcoat layer 35 is in direct contact with the entire upper surface 30a of the sealing member 30. The lower surface 36 of the overcoat layer 35 is in direct contact with the top surface 25a of the reflective case 25. The lower surface 36 of the overcoat layer 35 is in direct contact with the entire top surface 25a of the reflective case 25. The upper surface 37 of the overcoat layer 35 is exposed to the surrounding environment (for example, air) of the semiconductor light emitting device 1.

The thickness of the overcoat layer 35 on the sealing member 30 and the reflective case 25 is constant. In the present disclosure, the constant thickness of the overcoat layer 35 means that a difference between the maximum thickness of the overcoat layer 35 and the minimum thickness of the overcoat layer 35 is within 20% of the maximum thickness of the overcoat layer 35. The minimum thickness of the overcoat layer 35 is, for example, 1 μm or more. The minimum thickness of the overcoat layer 35 may be 5 μm or more, 10 μm or more, or 20 μm or more. The maximum thickness of the overcoat layer 35 is, for example, 100 μm or less. The maximum thickness of the overcoat layer 35 may be 90 μm or less, 80 μm or less, or 70 m or less. The overcoat layer 35 is, for example, a spray coat layer formed by a coating method such as a spray coating method.

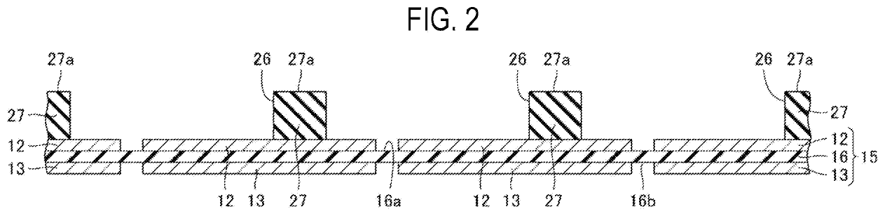

A method of manufacturing the semiconductor light emitting device 1 of this embodiment will be described with reference to FIGS. 2 to 6.

Referring to FIG. 2, the method of manufacturing the semiconductor light emitting device 1 of this embodiment includes a step of preparing a substrate connection body 15. The substrate connection body 15 includes a base member 16, front conductive layers 12, and back conductive layers 13. The base member 16 has a front surface 16a and a back surface 16b opposite to the front surface 16a. The base member 16 is formed of the same material as the insulating substrate 11. The front conductive layers 12 are separated from each other. The front conductive layers 12 are formed of the same material as the front conductive layers 12a and 12b (see FIG. 1). The back conductive layers 13 are separated from each other. The back conductive layers 13 are formed of the same material as the back conductive layers 13a and 13b (see FIG. 1).

Referring to FIG. 2, the method of manufacturing the semiconductor light emitting device 1 of this embodiment includes a step of attaching a reflective case connection body 27 to the substrate connection body 15. The reflective case connection body 27 is provided with a plurality of accommodation parts 26. The reflective case connection body 27 is obtained, for example, by insert-molding a synthetic resin to which a white filler is added. The reflective case connection body 27 is adhered to the substrate connection body 15 (more specifically, the front conductive layers 12) using an adhesive (not shown). The reflective case connection body 27 has a top surface 27a on the opposite side to the substrate connection body 15.

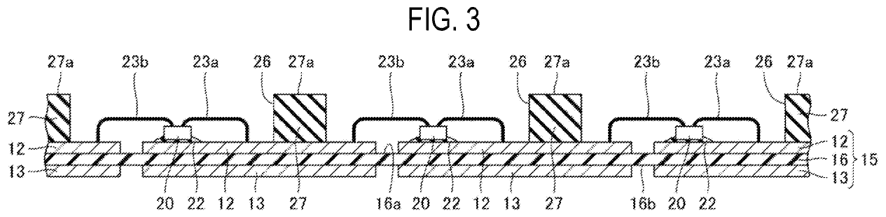

Referring to FIG. 3, the method of manufacturing the semiconductor light emitting device 1 of this embodiment includes a step of arranging a plurality of semiconductor light emitting elements 20 in the plurality of accommodation parts 26 of the reflective case connection body 27. Each of the plurality of accommodation parts 26 accommodates a corresponding one of the plurality of semiconductor light emitting elements 20. Specifically, the plurality of semiconductor light emitting elements 20 are bonded to the substrate connection body 15 (specifically, the front conductive layers 12) using the bonding member 22.

Referring to FIG. 3, the method of manufacturing the semiconductor light emitting device 1 of this embodiment includes a step of wiring conductive wires 23a and 23b. Specifically, the conductive wires 23a are connected to the plurality of semiconductor light emitting elements 20 (for example, n-type electrodes) and the front conductive layers 12. The conductive wires 23b are connected to the plurality of semiconductor light emitting elements 20 (for example, p-type electrodes) and the front conductive layers 12.

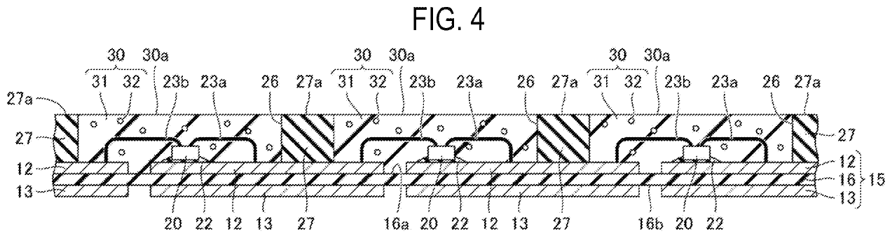

Referring to FIG. 4, the method of manufacturing the semiconductor light emitting device 1 of this embodiment includes a step of sealing the plurality of semiconductor light emitting elements 20 with the sealing member 30. Specifically, liquid sealing resin is injected into the plurality of accommodation parts 26 of the reflective case connection body 27. The liquid sealing resin includes the wavelength conversion member 32 such as phosphor particles. The plurality of semiconductor light emitting elements 20 are covered with the liquid sealing resin. Then, the liquid sealing resin is heated. The liquid sealing resin is thermally cured to become the sealing member 30. Thus, the plurality of semiconductor light emitting elements 20 are sealed with the sealing member 30.

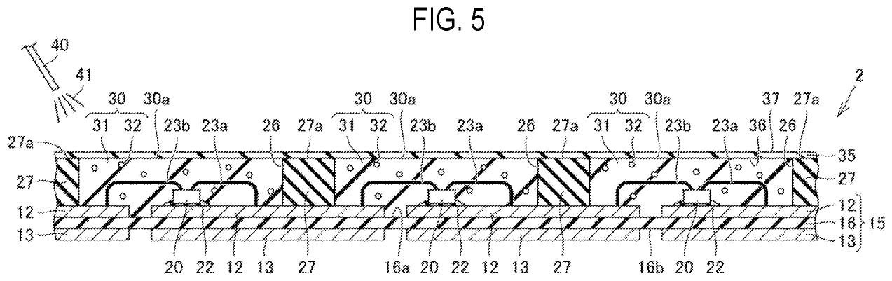

Referring to FIG. 5, the method of manufacturing the semiconductor light emitting device 1 of this embodiment includes a step of forming the overcoat layer 35 covering the sealing member 30 by a coating method such as a spray coating method. The step of forming the overcoat layer 35 is performed, for example, at room temperature. Specifically, a solution 41 is discharged from a nozzle 40. The solution 41 includes a solvent, such as methyl ethyl ketone, and a solute dispersed in the solvent. The solute includes, for example, inorganic material particles, such as silica particles, or inorganic material fillers such as silica fillers. The solution 41 is sprayed onto the upper surface 30a of the sealing member 30 to evaporate the solvent. Thus, the overcoat layer 35 is formed. The overcoat layer 35 is formed of an inorganic material. The inorganic material is, for example, SiO₂. The overcoat layer 35 covers the entire upper surface 30a of the sealing member 30 and is in direct contact with the entire upper surface 30a of the sealing member 30.

The overcoat layer 35 is also formed on the top surface 27a of the reflective case connection body 27. The overcoat layer 35 covers the entire top surface 27a of the reflective case connection body 27 and is in direct contact with the entire top surface 27a of the reflective case connection body 27. Thus, a light emitting device connection body 2 is obtained. The light emitting device connection body 2 mainly includes the substrate connection body 15, the reflective case connection body 27, the plurality of semiconductor light emitting elements 20, the conductive wires 23a and 23b, the sealing member 30, and the overcoat layer 35.

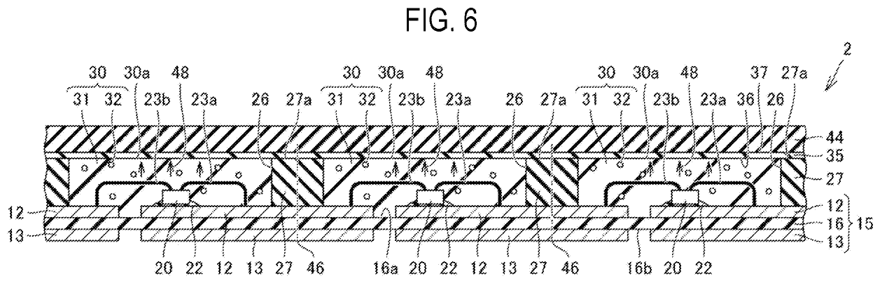

Referring to FIG. 6, the method of manufacturing the semiconductor light emitting device 1 of this embodiment includes a step of attaching a dicing tape 44 to the overcoat layer 35 of the light emitting device connection body 2, and a step of heating the dicing tape 44. By heating the dicing tape 44, the adhesion of the dicing tape 44 to the light emitting device connection body 2 is improved. The step of heating the dicing tape 44 is performed at a higher temperature than the step of forming the overcoat layer 35.

Referring to FIG. 6, the method of manufacturing the semiconductor light emitting device 1 of this embodiment includes a step of dicing the light emitting device connection body 2 into individual pieces. The light emitting device connection body 2 is cut along dicing lines 46 using a dicing blade (not shown) or a laser beam (not shown). The light emitting device connection body 2 is divided into a plurality of semiconductor light emitting devices 1. Specifically, when the light emitting device connection body 2 is cut, the base member 16 is divided into a plurality of insulating substrates 11, the front conductive layer 12 is divided into front conductive layers 12a and 12b, the back conductive layer 13 is divided into back conductive layers 13a and 13b, the substrate connection body 15 is divided into a plurality of substrates 10, and the reflective case connection body 27 is divided into a plurality of reflective cases 25. Each of the plurality of substrates 10 supports a corresponding one of the plurality of semiconductor light emitting elements 20. Each of the plurality of reflective cases 25 accommodates a corresponding one of the plurality of semiconductor light emitting elements 20. The dicing tape 44 is peeled off from the plurality of semiconductor light emitting devices 1. Thus, the semiconductor light emitting device 1 is obtained.

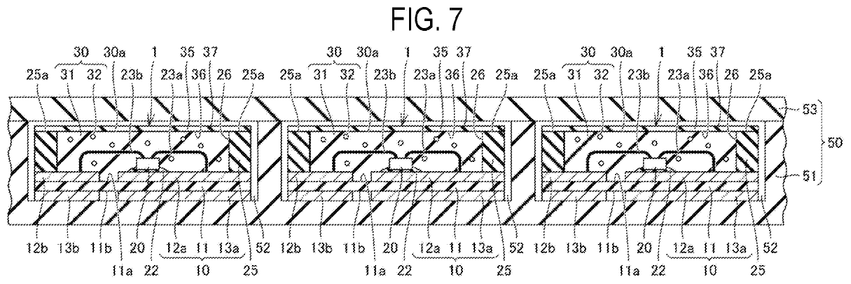

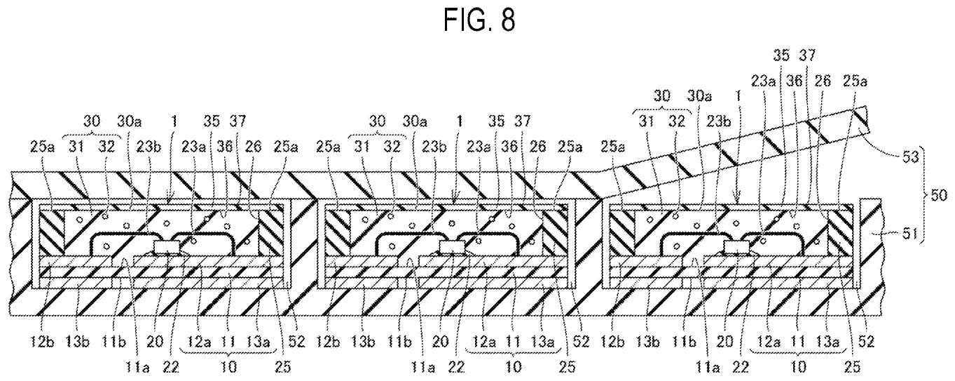

Referring to FIG. 7, the semiconductor light emitting devices 1 are accommodated in a package 50. The package 50 includes a carrier 51 and a top tape 53. A plurality of recesses 52 are provided in the carrier 51. The semiconductor light emitting device 1 is accommodated in each of the plurality of recesses 52. The carrier 51 may be strip-shaped and flexible. The top tape 53 closes openings of the recesses 52. The semiconductor light emitting devices 1 are transported and stored with the package 50 being wound up on a reel (not shown). Referring to FIG. 8, when using the semiconductor light emitting devices 1, the package 50 is drawn out from the reel, the top tape 53 is peeled off from the carrier 51, and the semiconductor light emitting devices 1 are taken out from the recesses 52 of the carrier 51 using a pickup device (not shown).

With reference to FIGS. 6 to 10, the operation of the semiconductor light emitting device 1 of this embodiment and the method of manufacturing the same will be described in comparison with a semiconductor light emitting device 6 of a comparative example and a method of manufacturing the same.

As shown in FIGS. 7 and 8, the semiconductor light emitting device 1 of this embodiment includes the overcoat layer 35 covering the sealing member 30. The sealing member 30 has adhesiveness due to the sealing resin 31, whereas the overcoat layer 35 does not have adhesiveness because it is formed of an inorganic material. Even if the semiconductor light emitting device 1 contacts the top tape 53 while the semiconductor light emitting device 1 is accommodated in the package 50, the overcoat layer 35 prevents the semiconductor light emitting device 1 from adhering to the top tape 53. As shown in FIG. 8, even if the top tape 53 is peeled off from the carrier 51 in order to use the semiconductor light emitting device 1, the semiconductor light emitting device 1 remains accommodated in the recess 52 of the carrier 51. Therefore, the semiconductor light emitting device 1 can be easily taken out from the package 50 using a pickup device (not shown).

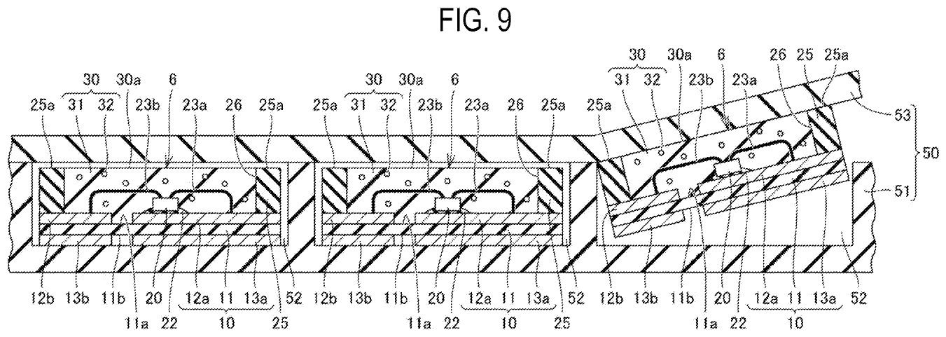

In contrast, referring to FIG. 9, the semiconductor light emitting device 6 of the comparative example is different from the semiconductor light emitting device 1 of this embodiment in that the former does not include the overcoat layer 35. In the semiconductor light emitting device 6 of the comparative example, a portion of the outermost surface of the semiconductor light emitting device 6 is the upper surface 30a of the sealing member 30. The sealing member 30 has adhesiveness due to the sealing resin 31. When the semiconductor light emitting device 6 contacts the top tape 53 while the semiconductor light emitting device 6 is accommodated in the package 50, the sealing member 30 adheres to the top tape 53, and the semiconductor light emitting device 6 adheres to the top tape 53. When the top tape 53 is peeled off from the carrier 51 in order to use the semiconductor light emitting device 6, the semiconductor light emitting device 6 attached to the top tape 53 slips out of the recess 52 of the carrier 51. Therefore, it is difficult to take out the semiconductor light emitting device 6 from the package 50 using a pickup device (not shown).

Referring to FIG. 6, when the dicing tape 44 is heated in order to improve adhesion of the dicing tape 44 to the light emitting device connection body 2 of this embodiment, the sealing member 30 is heated, and a gas 48 may be generated from the sealing resin 31. However, the overcoat layer 35 prevents the gas 48 from passing through the overcoat layer 35. Therefore, the adhesion of the dicing tape 44 to the light emitting device connection body 2 is improved. In this embodiment, the step of dicing the light emitting device connection body 2 into individual pieces, which includes the step of dividing the substrate connection body 15, can be performed more accurately and more stably.

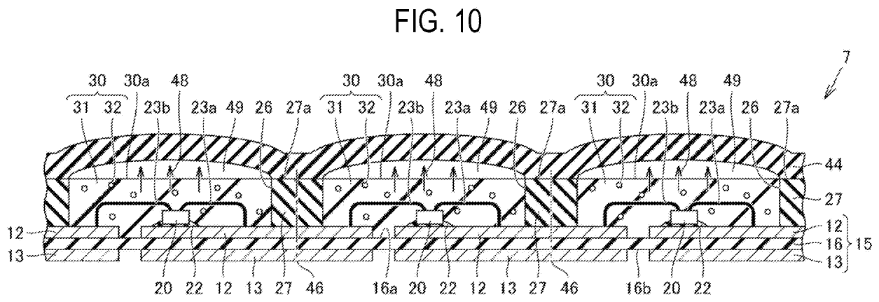

In contrast, referring to FIG. 10, a light emitting device connection body 7 of the comparative example is different from the light emitting device connection body 2 of this embodiment in that the former does not include the overcoat layer 35. The semiconductor light emitting device 6 (FIG. 9) of the comparative example is obtained by dicing the light emitting device connection body 7 into individual pieces. When the dicing tape 44 is heated, the sealing member 30 is heated, and a gas 48 is generated from the sealing resin 31. The gas 48 stays between the sealing member 30 and the dicing tape 44 and creates a gap 49 between the sealing member 30 and the dicing tape 44. The adhesion of the dicing tape 44 to the light emitting device connection body 7 is reduced. Therefore, in the comparative example, it is difficult to perform accurately and stably the step of dicing the light emitting device connection body 7 into individual pieces, which includes the step of dividing the substrate connection body 15.

### Modifications

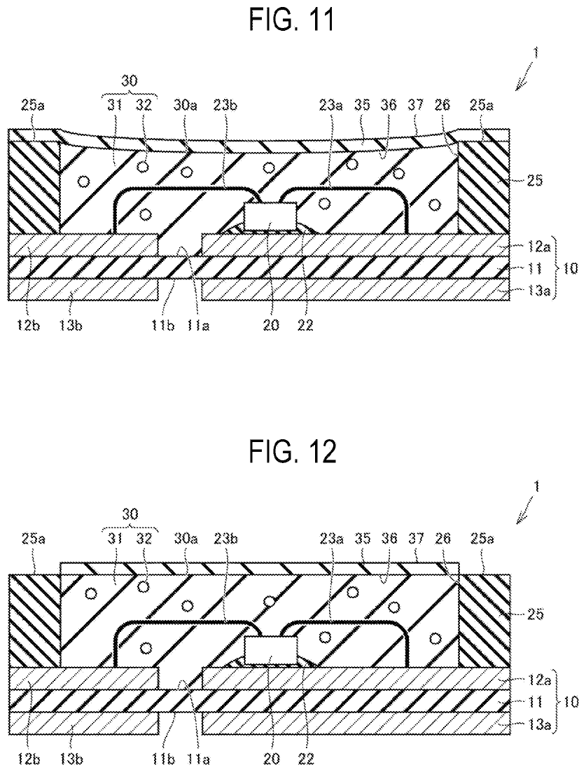

As shown in FIG. 11, in a first modification of the embodiment, the upper surface 30a of the sealing member 30 and the upper surface 37 of the overcoat layer 35 may be recessed. Therefore, the semiconductor light emitting device 1 is further prevented from adhering to the top tape 53 (see FIGS. 7 and 8). The semiconductor light emitting device 1 can be easily taken out from the package 50 using a pickup device (not shown).

As shown in FIG. 12, in a second modification of the embodiment, the top surface 25a of the reflective case 25 may be exposed from the overcoat layer 35.

The effects of the semiconductor light emitting device 1 of this embodiment and the method of manufacturing the same will be explained.

The semiconductor light emitting device 1 of this embodiment includes the semiconductor light emitting element 20, the sealing member 30 that seals the semiconductor light emitting element 20, and the overcoat layer 35 that covers the sealing member 30. The sealing member 30 includes the sealing resin 31 and has the first upper surface (the upper surface 30a) on the opposite side to the semiconductor light emitting element 20. The overcoat layer 35 is formed of an inorganic material and is in direct contact with the first upper surface of the sealing member 30.

Since the overcoat layer 35 is formed of the inorganic material, it does not have adhesiveness. Therefore, even if the sealing member 30 has adhesiveness due to the sealing resin 31, the semiconductor light emitting device 1 is prevented from adhering to the top tape 53 (see FIGS. 7 and 8) of the package 50. Even if the top tape 53 is peeled off from the carrier 51 in order to use the semiconductor light emitting device 1, the semiconductor light emitting device 1 remains accommodated in the recess 52 of the carrier 51. Therefore, the semiconductor light emitting device 1 can be easily taken out from the package 50 using a pickup device.

Further, when the dicing tape 44 is heated to improve the adhesion of the dicing tape 44 to the light emitting device connection body 2, the sealing member 30 may be heated, and a gas 48 may be generated from the sealing resin 31. However, the overcoat layer 35 prevents the gas 48 from passing through the overcoat layer 35. Therefore, the adhesion of the dicing tape 44 to the light emitting device connection body 2 is improved. The step of dicing the light emitting device connection body 2 into individual pieces, which includes the step of dividing the substrate connection body 15, can be performed more accurately and more stably.

In the semiconductor light emitting device 1 of this embodiment, the thickness of the overcoat layer 35 on the sealing member 30 is constant.

Therefore, the overcoat layer 35 can be made to follow the shape of the first upper surface (the upper surface 30a) of the sealing member 30.

In the semiconductor light emitting device 1 of this embodiment, the minimum thickness of the overcoat layer 35 on the sealing member 30 is 1 μm or more, and the maximum thickness of the overcoat layer 35 is 100 μm or less.

Since the minimum thickness of the overcoat layer 35 is 1 μm or more, the overcoat layer 35 more surely prevents the semiconductor light emitting device 1 from adhering to the top tape 53 of the package 50 and the gas 48 from passing through the overcoat layer 35. The semiconductor light emitting device 1 can be easily taken out from the package 50 using a pickup device. The adhesion of the dicing tape 44 to the light emitting device connection body 2 is improved. The step of dicing the light emitting device connection body 2 into individual pieces, which includes the step of dividing the substrate connection body 15, can be performed more accurately and more stably. Moreover, since the maximum thickness of the overcoat layer 35 is 100 μm or less, the time and cost required to form the overcoat layer 35 can be reduced.

The semiconductor light emitting device 1 of this embodiment further includes the reflective case 25. The semiconductor light emitting element 20 is accommodated in the reflective case 25. The overcoat layer 35 is in direct contact with the reflective case 25.

A step of removing the overcoat layer 35 from the reflective case 25 becomes unnecessary. Therefore, the cost of the semiconductor light emitting device 1 can be reduced.

In the semiconductor light emitting device 1 of this embodiment, the second upper surface (the upper surface 37) of the overcoat layer 35 on the opposite side to the sealing member 30 is recessed.

Therefore, the semiconductor light emitting device 1 is further prevented from adhering to the top tape 53 (see FIGS. 7 and 8). The semiconductor light emitting device 1 can be easily taken out from the package 50 using a pickup device.

In the semiconductor light emitting device 1 of this embodiment, the inorganic material is SiO₂.

Therefore, the overcoat layer 35 does not have adhesiveness. The overcoat layer 35 prevents the semiconductor light emitting device 1 from adhering to the top tape 53 of the package 50 and the gas 48 from passing through the overcoat layer 35. The semiconductor light emitting device 1 can be easily taken out from the package 50 using a pickup device. The adhesion of the dicing tape 44 to the light emitting device connection body 2 is improved. The step of dicing the light emitting device connection body 2 into individual pieces, which includes the step of dividing the substrate connection body 15, can be performed more accurately and more stably.

In the semiconductor light emitting device 1 of this embodiment, the sealing member 30 includes the wavelength conversion member 32 dispersed in the sealing resin 31. The wavelength conversion member 32 converts the wavelength of light emitted from the semiconductor light emitting element 20 and is provided only in the sealing member 30 out of the sealing member 30 and the overcoat layer 35.

The overcoat layer 35 does not have adhesiveness. The overcoat layer 35 prevents the semiconductor light emitting device 1 from adhering to the top tape 53 of the package 50 and the gas 48 from passing through the overcoat layer 35. The semiconductor light emitting device 1 can be easily taken out from the package 50 using a pickup device. The adhesion of the dicing tape 44 to the light emitting device connection body 2 is improved. The step of dicing the light emitting device connection body 2 into individual pieces, which includes the step of dividing the substrate connection body 15, can be performed more accurately and more stably.

The method of manufacturing the semiconductor light emitting device 1 of this embodiment includes the step of bonding a plurality of semiconductor light emitting elements 20 to the substrate connection body 15, the step of sealing the plurality of semiconductor light emitting elements 20 with the sealing member 30, the step of forming the overcoat layer 35 covering the sealing member 30 by a coating method, and the step of dividing the substrate connection body 15 into a plurality of substrates 10. Each of the plurality of substrates 10 supports a corresponding one of the plurality of semiconductor light emitting elements 20. The sealing member 30 includes the sealing resin 31 and has the first upper surface (the upper surface 30a) on the opposite side to the semiconductor light emitting element 20. The overcoat layer 35 is formed of an inorganic material and is in direct contact with the first upper surface of the sealing member 30.

Since the overcoat layer 35 is formed of the inorganic material, it does not have adhesiveness. Therefore, even if the sealing member 30 has adhesiveness due to the sealing resin 31, the semiconductor light emitting device 1 is prevented from adhering to the top tape 53 (see FIGS. 7 and 8) of the package 50. Even if the top tape 53 is peeled off from the carrier 51 in order to use the semiconductor light emitting device 1, the semiconductor light emitting device 1 remains accommodated in the recess 52 of the carrier 51. Therefore, the semiconductor light emitting device 1 can be easily taken out from the package 50 using a pickup device.

The overcoat layer 35 is formed by a coating method. According to the coating method, the overcoat layer 35 can be formed without heating the sealing resin 31. Therefore, when forming the overcoat layer 35, deterioration of the sealing member 30 such as discoloration of the sealing resin 31 can be avoided. A fluctuation in the color temperature of the light emitted from the semiconductor light emitting device 1, a decrease in the intensity of the light emitted from the semiconductor light emitting device 1, and a decrease in the reliability of the semiconductor light emitting device 1 can be suppressed.

In the method of manufacturing the semiconductor light emitting device 1 of this embodiment, the coating method is a spray coating method.

The overcoat layer 35 is formed by a spray coating method. According to the spray coating method, the overcoat layer 35 can be formed without heating the sealing resin 31. Therefore, when forming the overcoat layer 35, deterioration of the sealing member 30 such as discoloration of the sealing resin 31 can be avoided. A fluctuation in the color temperature of the light emitted from the semiconductor light emitting device 1, a decrease in the intensity of the light emitted from the semiconductor light emitting device 1, and a decrease in the reliability of the semiconductor light emitting device 1 can be suppressed.

The method of manufacturing the semiconductor light emitting device 1 of this embodiment further includes the step of attaching the dicing tape 44 to the overcoat layer 35, and the step of heating the dicing tape 44.

When the dicing tape 44 is heated to improve the adhesion of the dicing tape 44 to the light emitting device connection body 2, the sealing member 30 may be heated, and a gas 48 may be generated from the sealing resin 31. However, the overcoat layer 35 prevents the gas 48 from passing through the overcoat layer 35. Therefore, the adhesion of the dicing tape 44 to the light emitting device connection body 2 is improved. The step of dicing the light emitting device connection body 2 into individual pieces, which includes the step of dividing the substrate connection body 15, can be performed more accurately and more stably.

In the method of manufacturing the semiconductor light emitting device 1 of this embodiment, the thickness of the overcoat layer 35 on the sealing member 30 is constant.

Therefore, the overcoat layer 35 can be made to follow the shape of the first upper surface (the upper surface 30a) of the sealing member 30.

In the method of manufacturing the semiconductor light emitting device 1 of this embodiment, the minimum thickness of the overcoat layer 35 on the sealing member 30 is 1 μm or more, and the maximum thickness of the overcoat layer 35 is 100 μm or less.

Since the minimum thickness of the overcoat layer 35 is 1 μm or more, the overcoat layer 35 more surely prevents the semiconductor light emitting device 1 from adhering to the top tape 53 of the package 50 and the gas 48 from passing through the overcoat layer 35. The semiconductor light emitting device 1 can be easily taken out from the package 50 using a pickup device. The adhesion of the dicing tape 44 to the light emitting device connection body 2 is improved. The step of dicing the light emitting device connection body 2 into individual pieces, which includes the step of dividing the substrate connection body 15, can be performed more accurately and more stably. Moreover, since the maximum thickness of the overcoat layer 35 is 100 μm or less, the time and cost required to form the overcoat layer 35 can be reduced.

The method of manufacturing the semiconductor light emitting device 1 of this embodiment further includes the step of attaching the reflective case connection body 27 to the substrate connection body 15, and the step of dividing the reflective case connection body 27 into a plurality of reflective cases 25. Each of the plurality of reflective cases 25 accommodates a corresponding one of the plurality of semiconductor light emitting elements 20. In the step of forming the overcoat layer 35, the overcoat layer 35 is also formed on the reflective case connection body 27. The overcoat layer 35 is also in direct contact with the reflective case connection body 27.

A step of removing the overcoat layer 35 from the reflective case 25 becomes unnecessary. Therefore, the manufacturing cost of the semiconductor light emitting device 1 can be reduced.

In the method of manufacturing the semiconductor light emitting device 1 of this embodiment, the second upper surface (the upper surface 37) of the overcoat layer 35 on the opposite side to the sealing member 30 is recessed.

Therefore, the semiconductor light emitting device 1 is further prevented from adhering to the top tape 53 (see FIGS. 7 and 8). The semiconductor light emitting device 1 can be easily taken out from the package 50 using a pickup device.

In the method of manufacturing the semiconductor light emitting device 1 of this embodiment, the inorganic material is SiO₂.

Therefore, the overcoat layer 35 does not have adhesiveness. The overcoat layer 35 prevents the semiconductor light emitting device 1 from adhering to the top tape 53 of the package 50 and the gas 48 from passing through the overcoat layer 35. The semiconductor light emitting device 1 can be easily taken out from the package 50 using a pickup device. The adhesion of the dicing tape 44 to the light emitting device connection body 2 is improved. The step of dicing the light emitting device connection body 2 into individual pieces, which includes the step of dividing the substrate connection body 15, can be performed more accurately and more stably.

In the method of manufacturing the semiconductor light emitting device 1 of this embodiment, the sealing member 30 includes the wavelength conversion member 32 dispersed in the sealing resin 31. The wavelength conversion member 32 converts the wavelength of light emitted from the semiconductor light emitting element 20 and is provided only in the sealing member 30 out of the sealing member 30 and the overcoat layer 35.

The overcoat layer 35 does not have adhesiveness. The overcoat layer 35 prevents the semiconductor light emitting device 1 from adhering to the top tape 53 of the package 50 and the gas 48 from passing through the overcoat layer 35. The semiconductor light emitting device 1 can be easily taken out from the package 50 using a pickup device. The adhesion of the dicing tape 44 to the light emitting device connection body 2 is improved. The step of dicing the light emitting device connection body 2 into individual pieces, which includes the step of dividing the substrate connection body 15, can be performed more accurately and more stably.

Hereinafter, various aspects of the present disclosure will be collectively described as supplementary notes.

### (Supplementary Note 1)

A semiconductor light emitting device including:
a semiconductor light emitting element;
a sealing member that seals the semiconductor light emitting element; and
an overcoat layer that covers the sealing member,
wherein the sealing member includes a sealing resin and has a first upper surface on an opposite side to the semiconductor light emitting element, and
wherein the overcoat layer is formed of an inorganic material and is in direct contact with the first upper surface of the sealing member.

### (Supplementary Note 2)

The semiconductor light emitting device of Supplementary Note 1, wherein a thickness of the overcoat layer on the sealing member is constant.

### (Supplementary Note 3)

The semiconductor light emitting device of Supplementary Note 1 or 2, wherein a minimum thickness of the overcoat layer on the sealing member is 1 μm or more, and a maximum thickness of the overcoat layer on the sealing member is 100 μm or less.

### (Supplementary Note 4)

The semiconductor light emitting device of any one of Supplementary Notes 1 to 3, further including:
a reflective case,
wherein the semiconductor light emitting element is accommodated in the reflective case, and
wherein the overcoat layer is in direct contact with the reflective case.

### (Supplementary Note 5)

The semiconductor light emitting device of any one of Supplementary Notes 1 to 4, wherein a second upper surface of the overcoat layer, on an opposite side to the sealing member, is recessed.

### (Supplementary Note 6)

The semiconductor light emitting device of any one of Supplementary Notes 1 to 5, wherein the inorganic material is SiO₂.

### (Supplementary Note 7)

The semiconductor light emitting device of any one of Supplementary Notes 1 to 6, wherein the sealing member includes a wavelength conversion member dispersed in the sealing resin,
wherein the wavelength conversion member converts a wavelength of light emitted from the semiconductor light emitting element, and
wherein the wavelength conversion member is provided at the sealing member and is not provided at the overcoat layer.

### (Supplementary Note 8)

A method of manufacturing a semiconductor light emitting device, including:
bonding a plurality of semiconductor light emitting elements to a substrate connection body;
sealing the plurality of semiconductor light emitting elements with a sealing member;
forming an overcoat layer covering the sealing member by a coating method; and
dividing the substrate connection body into a plurality of substrates,
wherein each of the plurality of substrates supports a corresponding one of the plurality of semiconductor light emitting elements,
wherein the sealing member includes a sealing resin and has a first upper surface on an opposite side to the plurality of semiconductor light emitting elements, and
wherein the overcoat layer is formed of an inorganic material and is in direct contact with the first upper surface of the sealing member.

### (Supplementary Note 9)

The method of Supplementary Note 8, wherein the coating method is a spray coating method.

### (Supplementary Note 10)

The method of Supplementary Note 8 or 9, further including:
attaching a dicing tape to the overcoat layer; and
heating the dicing tape.

### (Supplementary Note 11)

The method of any one of Supplementary Notes 8 to 10, wherein a thickness of the overcoat layer on the sealing member is constant.

### (Supplementary Note 12)

The method of any one of Supplementary Notes 8 to 11, wherein a minimum thickness of the overcoat layer on the sealing member is 1 μm or more, and a maximum thickness of the overcoat layer on the sealing member is 100 μm or less.

### (Supplementary Note 13)

The method of any one of Supplementary Notes 8 to 12, further including:
attaching a reflective case connection body to the substrate connection body; and
dividing the reflective case connection body into a plurality of reflective cases,
wherein each of the plurality of reflective cases accommodates a corresponding one of the plurality of semiconductor light emitting devices,
wherein in forming the overcoat layer, the overcoat layer is formed on the reflective case connection body, and
wherein the overcoat layer is in direct contact with the reflective case connection body.

### (Supplementary Note 14)

The method of any one of Supplementary Notes 8 to 13, wherein a second upper surface of the overcoat layer, which is on an opposite side to the sealing member, is recessed.

### (Supplementary Note 15)

The method of any one of Supplementary Notes 8 to 14, wherein the inorganic material is SiO₂.

### (Supplementary Note 16)

The method of any one of Supplementary Notes 8 to 15, wherein the sealing member includes a wavelength conversion member dispersed in the sealing resin,
wherein the wavelength conversion member converts a wavelength of light emitted from the semiconductor light emitting element, and
wherein the wavelength conversion member is provided at the sealing member and is not provided at the overcoat layer.

The embodiments disclosed herein should be considered to be illustrative in all respects and not restrictive. The scope of the present disclosure is indicated by the claims rather than the above description, and it is intended that all changes within the meaning and range equivalent to the claims are included.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the scope of the disclosures. The accompanying claims and their equivalents are intended to cover such forms or modifications as would fall within the scope of the disclosures.

What is claimed is:

1. A semiconductor light emitting device comprising:
a semiconductor light emitting element;
a sealing member that seals the semiconductor light emitting element; and
an overcoat layer that covers the sealing member,
wherein the sealing member includes a sealing resin and has a first upper surface on an opposite side to the semiconductor light emitting element, and
wherein the overcoat layer is formed of an inorganic material and is in direct contact with the first upper surface of the sealing member.

2. The semiconductor light emitting device of claim 1, wherein a thickness of the overcoat layer on the sealing member is constant.

3. The semiconductor light emitting device of claim 1, wherein a minimum thickness of the overcoat layer on the sealing member is 1 μm or more, and a maximum thickness of the overcoat layer on the sealing member is 100 μm or less.

4. The semiconductor light emitting device of claim 1, further comprising:
a reflective case,
wherein the semiconductor light emitting element is accommodated in the reflective case, and
wherein the overcoat layer is in direct contact with the reflective case.

5. The semiconductor light emitting device of claim 1, wherein a second upper surface of the overcoat layer, on an opposite side to the sealing member, is recessed.

6. The semiconductor light emitting device of claim 1, wherein the inorganic material is SiO₂.

7. The semiconductor light emitting device of claim 1, wherein the sealing member includes a wavelength conversion member dispersed in the sealing resin,
wherein the wavelength conversion member converts a wavelength of light emitted from the semiconductor light emitting element, and
wherein the wavelength conversion member is provided at the sealing member and is not provided at the overcoat layer.

8. A method of manufacturing a semiconductor light emitting device, comprising:
bonding a plurality of semiconductor light emitting elements to a substrate connection body;
sealing the plurality of semiconductor light emitting elements with a sealing member;
forming an overcoat layer covering the sealing member by a coating method; and
dividing the substrate connection body into a plurality of substrates,
wherein each of the plurality of substrates supports a corresponding one of the plurality of semiconductor light emitting elements,
wherein the sealing member includes a sealing resin and has a first upper surface on an opposite side to the plurality of semiconductor light emitting elements, and
wherein the overcoat layer is formed of an inorganic material and is in direct contact with the first upper surface of the sealing member.

9. The method of claim 8, wherein the coating method is a spray coating method.

10. The method of claim 8, further comprising:
attaching a dicing tape to the overcoat layer; and
heating the dicing tape.

11. The method of claim 8, wherein a thickness of the overcoat layer on the sealing member is constant.

12. The method of claim 8, wherein a minimum thickness of the overcoat layer on the sealing member is 1 μm or more, and a maximum thickness of the overcoat layer on the sealing member is 100 μm or less.

13. The method of claim 8, further comprising:
attaching a reflective case connection body to the substrate connection body; and
dividing the reflective case connection body into a plurality of reflective cases,
wherein each of the plurality of reflective cases accommodates a corresponding one of the plurality of semiconductor light emitting devices,
wherein in forming the overcoat layer, the overcoat layer is formed on the reflective case connection body, and
wherein the overcoat layer is in direct contact with the reflective case connection body.

14. The method of claim 8, wherein a second upper surface of the overcoat layer, which is on an opposite side to the sealing member, is recessed.

15. The method of claim 8, wherein the inorganic material is SiO₂.

16. The method of claim 8, wherein the sealing member includes a wavelength conversion member dispersed in the sealing resin,
wherein the wavelength conversion member converts a wavelength of light emitted from the semiconductor light emitting element, and
wherein the wavelength conversion member is provided at the sealing member and is not provided at the overcoat layer.
